(19) United States
(12) Patent Application Publication
(10) Pub. No.: US 2025/0048814 A1
(43) Pub. Date: Feb. 6, 2025

(54) DISPLAY PANEL, MANUFACTURING METHOD THEREFOR, AND DISPLAY DEVICE

(71) Applicants: Mianyang BOE Optoelectronics Technology Co., Ltd., Mianyang, Sichuan (CN); BOE Technology Group Co., Ltd., Beijing (CN)

(72) Inventors: Qing TANG, Beijing (CN); Zifeng WANG, Beijing (CN); Haoyuan FAN, Beijing (CN)

(21) Appl. No.: 18/580,126

(22) PCT Filed: Apr. 18, 2023
(86) PCT No.: PCT/CN2023/089022

§ 371 Date: Jan. 17, 2024

(30) Foreign Application Priority Data
Apr. 20, 2022 (CN) 202210420595.0

(51) Int. Cl. H01L 33/62; H01L 25/075

(52) U.S. Cl. CPC H01L 33/62; H01L 25/0753; H01L 2933/0066

(57) ABSTRACT

Provided is a display panel. The display panel includes: a substrate, an insulating layer disposed on the substrate and provided with a patterned groove; and a first trace pattern and a second trace pattern, wherein the first trace pattern is disposed in the groove, the second trace pattern is disposed on the insulating layer, and the first trace pattern and the second trace pattern are patterns formed by fracture at an edge of the groove.

### CROSS-REFERENCE TO RELATED APPLICATION

This application is a U.S. national stage of international application No. PCT/CN2023/089022, filed on Apr. 18, 2023, which claims priority to Chinese Patent Application No. 202210420595.0, filed on Apr. 20, 2022, and entitled “DISPLAY PANEL, MANUFACTURING METHOD OF DISPLAY PANEL AND DISPLAY DEVICE,” the disclosures of which are herein incorporated by reference in their entireties.

### TECHNICAL FIELD

The present disclosure relates to the field of display technologies, and in particular, to a display panel, a manufacturing method therefor, and a display device.

### BACKGROUND

The display panel is a device capable of implementing an image display function, and the display panel usually includes a plurality of trace patterns at different layers for connecting various structures in the display panel.

### SUMMARY

Embodiments of the present disclosure provide a display panel, a manufacturing method therefor, and a display device. The technical solutions are as follows.

According to one aspect of the embodiments of the present disclosure, a display panel is provided. The display panel includes:
a substrate,
an insulating layer disposed on the substrate and provided with a patterned groove; and
a first trace pattern and a second trace pattern, wherein the first trace pattern is disposed in the groove, the second trace pattern is disposed on the insulating layer, and the first trace pattern and the second trace pattern are patterns formed by fracture at an edge of the groove.

In some embodiments, the display panel further includes a shielding pattern, wherein the shielding pattern is disposed between the second trace pattern and the insulating layer, an orthographic projection of the second trace pattern on the substrate is within an orthographic projection of the shielding pattern on the substrate, and an edge of the shielding pattern protrudes out of an edge of an end, distal from the substrate, of a groove wall of the groove.

In some embodiments, the material of the shielding pattern is a conductive material.

In some embodiments, the material of the shielding pattern includes indium tin oxide, and the insulating layer is an inorganic insulating layer.

In some embodiments, the groove includes one or more first groove walls, wherein the first groove wall and the substrate are perpendicular to each other, and the first trace pattern and the second trace pattern are patterns formed by fracture at the first groove wall.

In some embodiments, the display panel further includes a bridging line, wherein the groove includes one or more second groove walls, an obtuse included angle is formed between the second groove wall and a groove bottom, and the bridging line is bridged on the second groove wall with one end disposed on the insulating layer and the other end connected to the first trace patterns.

In some embodiments, the bridging line and the first trace pattern are in a same layer.

In some embodiments, the display panel further includes a first planarization layer, a third trace pattern, a second planarization layer, a source-drain trace pattern, a third planarization layer, and an anode pattern, which are sequentially stacked, along a direction away from the substrate, on the substrate having the second trace pattern.

In some embodiments, the display panel includes a light-transmitting display region and a conventional display region at least partially surrounding the light-transmitting display region, wherein the conventional display region includes a plurality of light-emitting devices and a plurality of pixel drive circuits, the plurality of pixel drive circuits include a plurality of first pixel drive circuits and a plurality of second pixel drive circuits, and the plurality of first pixel drive circuits are electrically connected to the light-emitting devices disposed in the conventional display region; and
the light-transmitting display region includes a light-emitting device, wherein the plurality of second pixel drive circuits are electrically connected, through the first trace pattern and the second trace pattern, to the light-emitting device disposed in the light-transmitting display region.

In some embodiments, the materials of the first trace pattern and the second trace pattern include indium tin oxide.

In some embodiments, the display panel includes a display region, wherein the first trace pattern and the second trace pattern are both disposed in the display region.

According to another aspect of the embodiments of the present disclosure, a method for manufacturing a display panel is provided. The method includes:
providing a substrate;
forming an insulating material layer on the substrate;
acquiring an insulating layer by forming a patterned groove on the insulating material layer; and
forming a first trace pattern and a second trace pattern on the insulating layer, wherein the first trace pattern is disposed in the groove, the second trace pattern is disposed on the insulating layer, and the first trace pattern and the second trace pattern are patterns formed by fracture at an edge of the groove.

In some embodiments, acquiring the insulating layer by forming the patterned groove on the insulating material layer includes:
forming a shielding pattern on the insulating material layer; and
acquiring the insulating layer with the patterned groove by processing the insulating material layer, wherein an edge of the shielding pattern protrudes out of an edge of an end, distal from the substrate, of a groove wall of the groove; and
forming the first trace pattern and the second trace pattern on the insulating layer includes:
forming a conductive material layer on the substrate having the insulating layer formed thereon, the conductive material layer fracturing at the edge of the groove; and
acquiring the first trace pattern and the second trace pattern by processing the conductive material layer.

In some embodiments, a material of the shielding pattern includes indium tin oxide, and forming the shielding pattern on the insulating material layer includes:
forming an indium tin oxide layer on the insulating material layer; and
acquiring the shielding pattern by wet-etching the indium tin oxide layer.

In some embodiments, acquiring the insulating layer with the patterned groove by processing the insulating material layer includes:
forming a photoresist pattern on the substrate having the shielding pattern formed thereon, wherein an orthographic projection of the shielding pattern on the substrate is within an orthographic projection of the photoresist pattern on the substrate; and
acquiring the insulating layer with the patterned groove by processing the insulating material layer by taking the photoresist pattern as a mask.

In some embodiments, the insulating layer is an inorganic insulating layer, and acquiring the insulating layer with the patterned groove by processing the insulating material layer by taking the photoresist pattern as the mask includes:
acquiring the insulating layer with the patterned groove by performing dry-etching on the insulating material layer by taking the photoresist pattern as the mask.

In some embodiments, acquiring the first trace pattern and the second trace pattern by processing the conductive material layer includes:
coating the conductive material layers with a photoresist layer;
processing the photoresist layer into a photoresist pattern through an exposure process and a development process; and
acquiring the first trace pattern and the second trace pattern by processing the conductive material layer by taking the photoresist pattern as a mask.

According to another aspect of the embodiments of the present disclosure, a display device is provided. The display device includes a sensor and the display panel described above.

In some embodiments, the sensor includes at least one of a biological sensor, an optical sensor, and a distance sensor.

In some embodiments, the display panel includes a light-transmitting display region and a conventional display region at least partially surrounding the light-transmitting display region, the sensor is disposed on a back surface of the display panel, and an overlapping region is present between an orthographic projection of the sensor on the display panel and the light-transmitting display region.

### BRIEF DESCRIPTION OF THE DRAWINGS

For clearer descriptions of the technical solutions provided by the embodiments of the present disclosure, the drawings to be referred to for the description of the embodiments are briefly introduced below. Apparently, the drawings in the description below merely illustrate some embodiments of the present disclosure, and those skilled in the art may also derive other drawings according to the drawings without creative efforts.

FIG. 1 is a schematic structural diagram of a display panel;

FIG. 2 is a schematic structural diagram of a display panel according to some embodiments of the present disclosure;

FIG. 3 is a schematic structural diagram of a part of the display panel shown in FIG. 2;

FIG. 4 is a schematic cross-sectional structural diagram of the display panel shown in FIG. 3;

FIG. 5 is a schematic structural diagram of another display panel according to some embodiments of the present disclosure;

FIG. 6 is a schematic structural diagram of another display panel according to some embodiments of the present disclosure;

FIG. 7 is a flowchart of a method for manufacturing a display panel according to some embodiments of the present disclosure;

FIG. 8 is a flowchart of another method for manufacturing a display panel according to some embodiments of the present disclosure;

FIG. 9 is a schematic structural diagram of structures on a substrate according to some embodiments of the present disclosure;

FIG. 10 is a schematic structural diagram of structures on another substrate according to some embodiments of the present disclosure;

FIG. 11 is a schematic structural diagram of structures on another substrate according to some embodiments of the present disclosure;

FIG. 12 is a schematic structural diagram of structures on another substrate according to some embodiments of the present disclosure; and

FIG. 13 is a schematic structural diagram of structures on another substrate according to some embodiments of the present disclosure.

The above drawings have shown some explicit embodiments of the present disclosure, which are described below in detail. These drawings and text descriptions are not intended to limit the scope of the conception of the present disclosure in any way, but to illustrate the concept of the present disclosure to those skilled in the art with reference to specific embodiments.

### DETAILED DESCRIPTION

For clearer descriptions of the objects, technical solutions, and advantages of the present disclosure, embodiments of the present disclosure are further described in detail hereinafter with reference to the drawings.

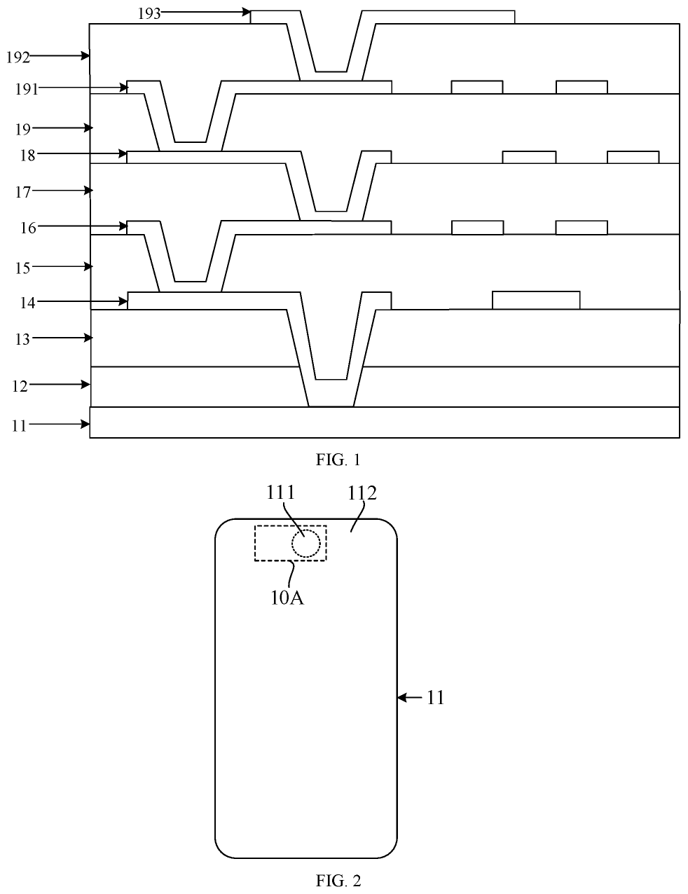

FIG. 1 is a schematic structural diagram of a display panel, in which the display panel includes a substrate 11, and a first insulating layer pattern 12, a first planarization layer pattern 13, a first trace pattern 14, a second planarization layer pattern 15, a second trace pattern 16, a third planarization layer pattern 17, a third trace pattern 18, a fourth planarization layer pattern 19, a fourth trace pattern 191, a fifth planarization layer pattern 192, and an anode pattern 193 that are sequentially stacked, along a direction away from the substrate, on the substrate 11, wherein each of the patterns needs to be formed by a patterning process, the number of patterning processes to be performed is large, and the number of masks to be used is large, and thus the cost is high, and the manufacturing process is complicated, resulting in high production cost of the display panel and long production cycle.

Embodiments of the present disclosure provide a display panel, a manufacturing method therefor, and a display device, which solve some problems in the prior art as described above.

At present, the front surface of the display device (the front surface of the display device refers to a side of the display device on which a display surface for displaying an image is disposed) generally needs to be provided with some sensors (such as a camera, a biological information sensor, an optical sensor, a distance sensor, etc.), but the sensors affect the screen-to-body ratio of a display panel. Therefore, one way to solve the problem is to set the display panel in the display device as a partially light-transmitting display panel, which improves the screen-to-body ratio of the display device. For example, the display panel includes a light-transmitting display region and a conventional display region disposed at the periphery of the light-transmitting display region. The light-transmitting display region is also referred to as a full display with camera (FDC) region. The conventional display region and the light-transmitting display region are both provided with light-emitting devices, such that both the conventional display region and the light-transmitting display region can display images.

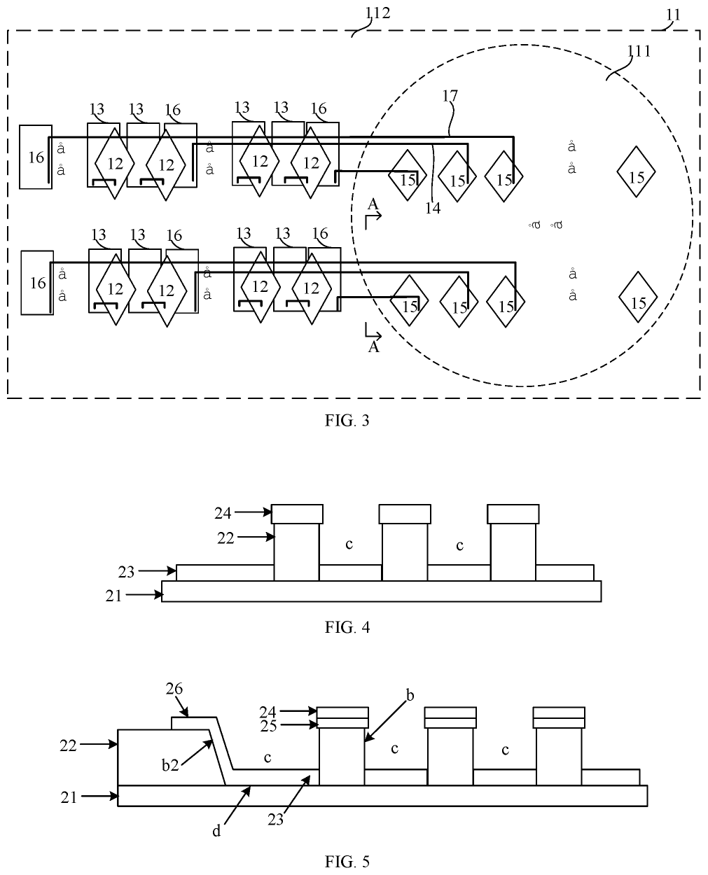

Referring to FIGS. 2 and 3, FIG. 2 is a schematic structural diagram of a display panel according to some embodiments of the present disclosure, and FIG. 3 is a schematic structural diagram of a part 10A of the display panel shown in FIG. 2. The display panel includes: a substrate 11, wherein the substrate 11 includes a light-transmitting display region 111 and a conventional display region 112 at least partially surrounding the light-transmitting display region 111, the conventional display region 112 being an opaque region.

The conventional display region 112 includes a plurality of light-emitting devices and a plurality of pixel drive circuits, the plurality of pixel drive circuits include a plurality of first pixel drive circuits 13 and a plurality of second pixel drive circuits 16, and the plurality of first pixel drive circuits 13 are electrically connected to the light-emitting devices (first light-emitting devices 12) disposed in the conventional display region 112.

The light-transmitting display region 111 includes a light-emitting device (second light-emitting devices 15), and the plurality of second pixel drive circuits 16 are electrically connected to the light-emitting devices (second light-emitting devices 15) disposed in the light-transmitting display region 111 through the first trace pattern 14 and the second trace pattern 17.

FIGS. 2 and 3 show a display panel to which the FDC technology is applied, but the display panel according to the embodiments of the present disclosure can also be a conventional display panel, that is, a display panel having only a conventional display region and not having an FDC region, and the embodiments of the present disclosure are not limited thereto.

FIG. 4 is a schematic cross-sectional (the cross-sectional position is A-A) structural diagram of the display panel shown in FIG. 3. The display panel includes:
a substrate 21; an insulating layer 22, wherein the insulating layer 22 is disposed on the substrate 21 and is provided with a patterned groove c; and
a first trace pattern 23 and a second trace pattern 24, wherein the first trace pattern 23 is disposed in the groove c, the second trace pattern 24 is disposed on the insulating layer 22, and the first trace pattern 23 and the second trace pattern 24 are patterns formed by fracture at an edge of the groove c.

It should be noted that the display panel may further include other structures for implementing a display function. In some embodiments, the display panel further includes other insulating layers and trace patterns disposed on the first trace pattern 23 and the second trace pattern 24, and further includes light-emitting devices and pixel drive circuits connected to the first trace pattern 23 and the second trace pattern 24, and the embodiments of the present disclosure are not limited thereto.

In summary, the embodiments of the present disclosure provide a display panel. The display panel includes a substrate, and a first trace pattern and a second trace pattern disposed on the substrate, wherein the two trace patterns are respectively disposed in a groove and on an insulating layer, and are formed by fracture at an edge of the groove, so it is not necessary to respectively process the insulating layer and the two trace patterns by patterning processes, thereby reducing the number of patterning processes, solving the problem that the manufacturing process of the display panel in some practices is complicated, and achieving an effect of simplifying the manufacturing process of the display panel.

In addition, as the number of patterning processes required for the manufacturing process of the display panel is reduced, the production cycle of the display panel is shortened, which is favorable for mass production of display panels.

FIG. 5 is a schematic structural diagram of another display panel according to some embodiments of the present disclosure. FIG. 5 is another schematic cross-sectional structure diagram of the display panel shown in FIG. 3 at A-A. The display panel further includes a shielding pattern 25, wherein the shielding pattern 25 is disposed between the second trace pattern 24 and the insulating layer 22, an orthographic projection of the second trace pattern 24 on the substrate 21 is within an orthographic projection of the shielding pattern 25 on the substrate 21, and an edge of the shielding pattern 25 protrudes out of an edge of an end (the upper end of FIG. 5), distal from the substrate 21, of a groove wall of the groove c.

Due to the presence of the shielding pattern 25, when etching the insulating layer 22 by using an etching method for the insulating layer 22, a part of the insulating layer under the shielding pattern 25 is also etched, but the shielding pattern 25 is almost not affected, and thus a structure in which the edge of the shielding pattern 25 protrudes out of the edge of the end, distal from the substrate 21, of a groove wall of the groove c is present, which is referred to as an undercut structure. Due to the presence of the undercut structure, upon a conductive structure layer is formed on the insulating layer 22 having the groove c, the conductive structure layer easily fractures at the edge of the groove c, so as to form a part of the structure disposed on the insulating layer 22 and another part of the structure disposed in the groove c. A part of the structure disposed on the insulating layer 22 includes the second trace pattern 24, and a part of the structure disposed in the groove includes the first trace pattern 23.

FIG. 5 shows a structure for facilitating the fracture of the first trace pattern 23 and the second trace pattern 24 at the edge of the groove c. However, the display panel according to the embodiments of the present disclosure also enables the first trace pattern 23 and the second trace pattern 24 to fracture at the edge of the groove c by other ways. In some embodiments, the depth of the groove c is made deep, and then the segment difference between the upper surface of the insulating layer 22 and the bottom of the groove c is large, which also facilitates the first trace pattern 23 and the second trace pattern 24 to fracture at the edge of the groove c. In some other embodiments, the material of the conductive material layer is adjusted such that the conductive material layer easily fractures at the edge of the groove c. In some embodiments, the first trace pattern 23 and the second trace pattern 24 are made of a light-transmitting conductive material to increase the light transmittance of the display panel. In some embodiments, the materials of the first trace pattern 23 and the second trace pattern 24 include indium tin oxide.

The material of the shielding pattern 25 includes a material that is hard to be etched by the etching process for the insulating layer 22.

In an exemplary embodiment, the material of the shielding pattern 25 is a conductive material. The conductive material is hard to be etched in the etching process for the insulating layer 22, and with this structure, the electrical performance of the second trace pattern 24 stacked with the shielding pattern 25 is enhanced, which is beneficial for the second trace pattern 24 to transmit an electrical signal.

In some embodiments, the material of the shielding pattern 25 includes indium tin oxide (ITO), and the insulating layer is an inorganic insulating layer. Indium tin oxide is a light-transmitting and conductive material that is hard to be etched in an etching process for an inorganic insulating layer such as a passivation layer (PVX) or a protective layer. In some embodiments, the shielding pattern 25 is formed by a patterning process, and an etching process in the patterning process for forming the shielding pattern 25 is wet etching; and the inorganic insulating layer is also formed by a patterning process, and an etching process in the patterning process for forming the inorganic insulating layer is dry etching. Indium tin oxide is hard to be etched in a dry etching process, thereby an undercut structure is easily formed.

It should be noted that the patterning process according to the embodiments of the present disclosure includes processes of coating with a photoresist, exposure, development, etching, and stripping the photoresist. Different etching processes are adopted for the film layers of different materials. For example, dry etching (dry etch for short) and wet etching (wet etch for short) are adopted.

In an exemplary embodiment, the groove c includes one or more first groove walls b, wherein the first groove wall b and the substrate 21 are perpendicular to each other, and the first trace pattern 23 and the second trace pattern 24 are patterns formed by fracture at the first groove wall b. The vertical groove wall b facilitates the fracture of the first trace pattern 23 and the second trace pattern 24 at the first groove wall b.

It should be noted that the first groove wall b and the substrate 21 are perpendicular to each other, which does not mean strictly perpendicular, but has an angle offset. In some embodiments, an included angle between the first groove wall b and the substrate 21 ranges from 100 degrees to 80 degrees, or an included angle between the first groove wall b and the substrate 21 ranges from 95 degrees to 85 degrees.

In an exemplary embodiment, as shown in FIG. 5, the insulating layer includes patterned protruding structures, and groove c is formed between the protruding structures. The protruding structures are provided with the shielding pattern 25, and also, the insulating layer also includes a part without the shielding pattern 25, which is not limited in the embodiments of the present disclosure. With this structure, a groove c is presented at each side of two sides of the shielding pattern 25, wherein the groove wall adjacent to the edge of the shielding pattern 25 is the first groove wall b; that is, the groove wall adjacent to the edge of the shielding pattern 25 is perpendicular to the substrate 21.

In an exemplary embodiment, the display panel further includes a bridging line 26, the groove c includes one or more second groove walls b2, an obtuse included angle is formed between the second groove wall b2 and a groove bottom d, and the bridging line 26 is bridged on the second groove wall with one end disposed on the insulating layer 22 and the other end connected to the first trace pattern 23. The bridging line 26 is used to connect the first trace pattern 23 with other lines on the upper layers, and because an obtuse included angle is formed between the second groove wall b2 and the groove bottom d, namely, a normal gradient angle is formed, the trace does not fracture when being bridged on the second groove wall b2, and then the bridging line 26 is connected to the first trace pattern 23 on the groove bottom d.

The shielding pattern 25 is not provided on the region, where one end of the bridging line 26 is disposed on, of the insulating layer 22, so an undercut structure is not formed at the second groove wall b2, and the second groove wall b2 has a regular gradient angle with the groove bottom d, which facilitates the arrangement of the bridging line 26.

In some embodiments, the bridging line 26 and the first trace pattern 23 are in a same layer. That is, the bridging line 26 and the first trace pattern 23 are made of the same material and are formed by a single process, so the number of patterning processes is reduced, the manufacturing cost of the display panel is reduced, and the production efficiency of the display panel is improved.

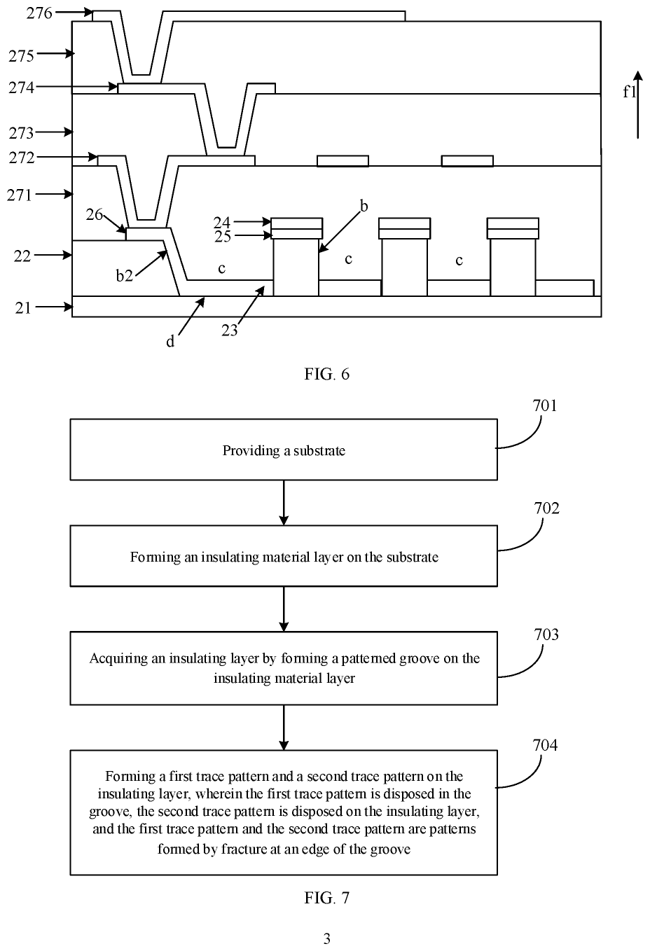

FIG. 6 is a schematic structural diagram of another display panel according to some embodiments of the present disclosure. FIG. 6 is another schematic cross-sectional structure diagram of the display panel shown in FIG. 3 at A-A. The display panel further includes a first planarization layer 271, a third trace pattern 272, a second planarization layer 273, a source-drain trace pattern 274, a third planarization layer 275, and an anode pattern 276, which are sequentially stacked on the substrate having the second trace pattern 24 along a direction fl away from the substrate 21. These structures are separately formed by corresponding patterning processes.

In an exemplary embodiment, the source-drain trace pattern 274 is made of the same material and in a same layer as a source line and a drain line in the conventional display region.

In addition, other lines or structures are arranged between the substrate and the insulating layer. In some embodiments, pixel drive circuits are arranged, which are not limited in the embodiments of the present disclosure.

In summary, the embodiments of the present disclosure provide a display panel. The display panel includes a substrate, and a first trace pattern and a second trace pattern disposed on the substrate, wherein the two trace patterns are respectively disposed in a groove and on an insulating layer, and are formed by fracture at an edge of the groove, so it is not necessary to separately process the insulating layer and the two trace patterns by patterning processes, thereby reducing the number of patterning processes, solving the problem that the manufacturing process of the display panel in some practices is complicated, and achieving an effect of simplifying the manufacturing process of the display panel.

In addition, because the number of patterning processes for the manufacturing process of the display panel is reduced, the production cycle of the display panel is shortened, which is favorable for the mass production of display panels.

FIG. 7 is a flowchart of a method for manufacturing a display panel according to some embodiments of the present disclosure. The method is used to manufacture the display panel as defined in the above embodiments, and the method includes the following processes.

In process 701, a substrate is provided.

In process 702, an insulating material layer is formed on the substrate.

In process 703, an insulating layer is acquired by forming a patterned groove on the insulating material layer.

In process 704, a first trace pattern and a second trace pattern are formed on the insulating layer, wherein the first trace pattern is disposed in the groove, the second trace pattern is disposed on the insulating layer, and the first trace pattern and the second trace pattern are patterns formed by fracture at an edge of the groove.

In summary, the embodiments of the present disclosure provide a method for manufacturing a display panel. The display panel manufactured by the method includes a substrate, and a first trace pattern and a second trace pattern disposed on the substrate, wherein the two trace patterns are respectively disposed in a groove and on an insulating layer, and are formed by fracture at an edge of the groove, so it is not necessary to separately process the insulating layer and the two trace patterns by patterning processes, thereby reducing the number of patterning processes, solving the problem that the manufacturing process of the display panel in some practices is complicated, and achieving an effect of simplifying the manufacturing process of the display panel.

In addition, because the manufacturing process of the display panel reduces the number of patterning processes, the production cycle of the display panel is shortened, which is favorable for mass production of display panels.

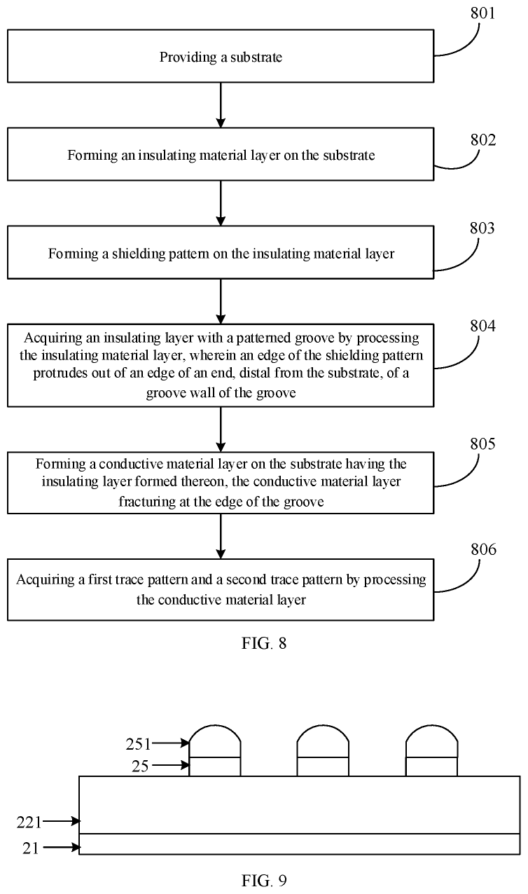

FIG. 8 is a flowchart of another method for manufacturing a display panel according to some embodiments of the present disclosure. The method includes the following processes.

In process 801, a substrate is provided.

The substrate is used to carry various structures in the display panel, and is, in some embodiments, a flexible substrate.

In process 802, an insulating material layer is formed on the substrate.

In some embodiments, the insulating material layer is a passivation layer, which is made of an inorganic insulating material. In some embodiments, the material of the insulating material layer includes silicon nitride, silicon oxide, and the like.

In process 803, a shielding pattern is formed on the insulating material layer.

The shape of the shielding pattern is referred to FIGS. 5 and 6 in the above embodiments.

In an exemplary embodiment, the material of the shielding pattern includes indium tin oxide, and process 803 includes the processes.
1. An indium tin oxide layer is formed on the insulating material layer.

The indium tin oxide layer is formed on the insulating material layer by a deposition process.
2. The shielding pattern is acquired by performing wet-etching on the indium tin oxide layer.

A photoresist pattern is first formed on the indium tin oxide layer, and then the indium tin oxide layer is wet-etched by taking the photoresist pattern as a mask to process the indium tin oxide layer into the shielding pattern. During the wet etching process, the used etching liquid does not influence the insulating material layer below. Upon wet etching, the structures on the substrate are shown in FIG. 9. FIG. 9 is a schematic diagram of structures on a substrate according to some embodiments of the present disclosure. As shown in the figure, an insulating material layer 221 is formed on the substrate 21, a shielding pattern 25 and a photoresist pattern 251 covering the shielding pattern are formed on the insulating material layer 221, and then the photoresist pattern 251 is stripped.

In process 804, the insulating layer with the patterned groove is acquired by processing the insulating material layer, wherein an edge of the shielding pattern protrudes out of an edge of an end, distal from the substrate, of a groove wall of the groove.

Because the process is aimed at the insulating material layer, the shielding pattern on the insulating material layer is not affected in the processing process, and then upon the process for the insulating material layer, the insulating layer under the shielding pattern is “retracted” relative to the shielding pattern, such that the edge of the shielding pattern protrudes out of the edge of an end, distal from the substrate, of groove wall of the groove.

In some embodiments, process 804 includes the following.
1. A photoresist pattern is formed on the substrate having the shielding pattern formed thereon, wherein an orthographic projection of the shielding pattern on the substrate is within an orthographic projection of the photoresist pattern on the substrate.

In some embodiments, the process includes forming a photoresist layer on the substrate having the shielding pattern formed thereon, and then the photoresist pattern is formed by exposing the photoresist layer using a mask. Because the shielding pattern does not need to be etched, the orthographic projection of the shielding pattern on the substrate is within the orthographic projection of the photoresist pattern on the substrate.
2. The insulating layer with the patterned groove is acquired by processing the insulating material layer by taking the photoresist pattern as a mask.

In some embodiments, the insulating layer with the patterned groove is acquired by performing dry etching on the insulating material layer by taking the photoresist pattern as the mask.

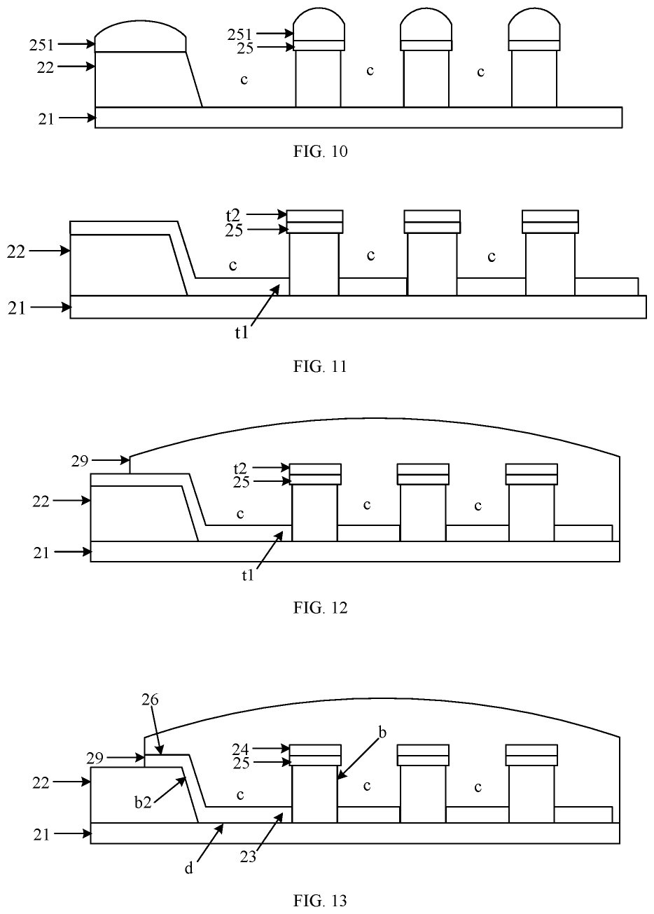

At the end of process 2, structures on the substrate are shown in FIG. 10. FIG. 10 is a schematic diagram of structures on another substrate according to some embodiments of the present disclosure. An insulating layer 22 having a patterned groove c is formed on a substrate 21, and a shielding pattern 25 and a photoresist pattern 251 which are sequentially stacked are formed on the insulating layer 22. The photoresist pattern 251 is subsequently stripped.

In process 805, a conductive material layer is formed on the substrate having the insulating layer formed thereon, the conductive material layer fracturing at an edge of the groove.

The material of the conductive material layer includes indium tin oxide, and the conductive material layer is formed on the substrate having the insulating layer formed thereon by a deposition process. At the end of process 805, structures on the substrate are shown in FIG. 11. FIG. 11 is a schematic diagram of structures on another substrate according to some embodiments of the present disclosure. An insulating layer 22 with a patterned groove c is formed on a substrate 21, a part of a conductive material pattern t2 is formed on a shielding pattern 25 on the insulating layer 22, and the part of the conductive material pattern t2 includes a second trace pattern; other parts of the conductive material pattern t1 are formed in the region except the shielding pattern 25 (e.g., in the groove c and on a part of the insulating layer), and this part of the conductive material pattern t1 includes first trace pattern and a bridging line.

As can be seen from FIG. 11, the conductive material layer on the insulating layer 22 having the shielding pattern 25 formed thereon is disconnected from the conductive material layer in the groove, but the conductive material layer on the insulating layer 22 having no shielding pattern 25 formed thereon is connected to the conductive material layer in the groove.

In process 806, the first trace pattern and the second trace pattern are acquired by processing the conductive material layer.

Because the conductive material pattern t2 currently including the second trace pattern and the conductive material pattern t1 including the first trace pattern and the bridging line may include a redundant conductive material layer, the conductive material patterns t1 and t2 are processed by another patterning process.

In the process, the conductive material layer is first coated with a photoresist layer, and the photoresist layer is processed into a photoresist pattern through an exposure process and a development process, and the specific structure can be referred to FIG. 12. FIG. 12 is a schematic structural diagram of structures on another substrate according to some embodiments of the present disclosure. The photoresist pattern 29 is formed on the conductive material patterns t1 and t2. Then, the conductive material patterns t1 and t2 are processed by taking the photoresist pattern as a mask to acquire the first trace pattern, the second trace pattern, and the bridging line. In some embodiments, referring to FIG. 13 which is a schematic structural diagram of structures on another substrate according to some embodiments of the present disclosure, upon the conductive material patterns t1 and t2 being processed by using the photoresist pattern 29, the first trace pattern 23, the second trace pattern 24, and the bridging line 26 are acquired, and the bridging line 26 is connected to the first trace pattern 23.

In some embodiments, the first trace pattern 23 and the second trace pattern 24 are used to connect the light-emitting devices in the light-transmitting display region and the pixel drive circuits in the conventional display region. Because a large number of light-emitting devices in the light-transmitting display region need to be connected to the pixel drive circuits in the conventional display region, it is difficult to achieve the effect through the traces in a single layer, and then one way for solving the problem is to connect the light-emitting devices in the light-transmitting display region to the pixel drive circuits in the conventional display region through traces in a plurality of layers, which leads to a large number of patterning processes. For example, the patterning processes for forming a plurality layers of trace patterns in the display panel as shown in FIG. 1 include: the patterning process of a passivation layer→the patterning process of a narrow lower frame→the patterning process of a first planarization layer→the patterning process of a source-drain metal pattern→the patterning process of a second planarization layer→the patterning process of a first trace pattern→the patterning process of a third planarization layer→the patterning process of a second trace pattern→the patterning process of a fourth planarization layer→the patterning process of a third trace pattern→the patterning process of a fifth planarization layer→the patterning process of an anode pattern→the patterning process of a pixel defining layer. The method requires many patterning processes and involves a complicated manufacturing process. However, the display panel according to the embodiments of the present disclosure is manufactured by fewer patterning processes. In some embodiments, the patterning processes include: the patterning process of the shielding pattern→the patterning process of the insulating layer→the patterning process of the narrow lower frame→the patterning process of the conductive material layer→the patterning process of the first planarization layer→the patterning process of the third trace pattern→the patterning process of the second planarization layer→the patterning process of the source-drain pattern→the patterning process of the third planarization layer→the patterning process of the anode pattern→the patterning process of the pixel definition layer. Compared with the display panel shown in FIG. 1, the number of patterning processes is reduced by 2.

In summary, the embodiments of the present disclosure provide a method for manufacturing a display panel. The display panel manufactured by the method includes a substrate, and a first trace pattern and a second trace pattern disposed on the substrate, wherein the two trace patterns are respectively disposed in a groove and on an insulating layer, and are formed by fracture at an edge of the groove, so it is not necessary to separately process the insulating layer and the two trace patterns by patterning processes, thereby reducing the number of patterning processes, solving the problem that the manufacturing process of the display panel in some practice is complicated, and achieving an effect of simplifying the manufacturing process of the display panel.

In addition, because the number of patterning processes in the manufacturing process of the display panel is reduced, the production cycle of the display panel is shortened, which is favorable for the mass production of display panels.

In addition, the embodiments of the present disclosure further provide a display device. The display device includes any one of the display panels as defined in the above embodiments.

In addition, the display device further includes a sensor, wherein the sensor is disposed on the back surface of the display panel, and an orthographic projection of the sensor on the display panel is within the light-transmitting display region of the display panel. The sensor includes a sensor such as a biological information sensor, an optical sensor, or a distance sensor.

In addition, as the display panel in the display device is any one of the display panels according to the above embodiments, and further, the display device also achieves a corresponding technical effect; namely, the display panel includes a substrate, and a first trace pattern and a second trace pattern disposed on the substrate, wherein the two trace patterns are respectively disposed in the groove and on the insulating layer, and are two trace patterns formed by fracture at an edge of the groove, so it is not necessary to separately process the insulating layer and the two trace patterns by patterning processes, thereby reducing the number of patterning processes, solving the problem that the manufacturing process of the display panel in some practice is complicated, and achieving an effect of simplifying the manufacturing process of the display panel.

In addition, because the number of patterning processes in the manufacturing process of the display panel is reduced, the production cycle of the display panel is shortened, which is favorable for the mass production of display panels and display devices.

It should be noted that, in the drawings, the sizes of the layers and regions may be exaggerated for clarity of illustration. Also, it can be understood that, in a case that an element or layer is referred to as being “on” another element or layer, it may be directly on the other element, or an intermediate layer may be present. In addition, it can be understood that, in a case that an element or layer is referred to as being “under” another element or layer, it may be directly under the other element, or one or more intermediate layers or elements may be present. In addition, it can also be understood that, in a case that a layer or element is referred to as being “between” two layers or elements, it may be the only layer between the two layers or elements, or one or more intermediate layers or elements may also be present. Like reference numerals refer to like elements throughout the present disclosure.

In the present disclosure, the terms “first,” “second,” “third,” “fourth,” and “fifth” are merely used for descriptive purposes and should not be construed as indicating or implying relative importance. The term “a plurality of” refers to two or more, unless otherwise explicitly defined.

Described above are merely optional embodiments of the present disclosure and are not intended to limit the present disclosure. Any modifications, equivalents, improvements, and the like, made within the concept and principle of the present disclosure fall within the protection scope of the present disclosure.

1. A display panel, comprising:
a substrate,
an insulating layer disposed on the substrate and provided with a patterned groove; and
a first trace pattern and a second trace pattern, wherein the first trace pattern is disposed in the groove, the second trace pattern is disposed on the insulating layer, and the first trace pattern and the second trace pattern are patterns formed by fracture at an edge of the groove.

2. The display panel according to claim 1, further comprising a shielding pattern, wherein the shielding pattern is disposed between the second trace pattern and the insulating layer, an orthographic projection of the second trace pattern on the substrate is within an orthographic projection of the shielding pattern on the substrate, and an edge of the shielding pattern protrudes out of an edge of an end, distal from the substrate, of a groove wall of the groove.

3. The display panel according to claim 2, wherein a material of the shielding pattern is a conductive material.

4. The display panel according to claim 3, wherein the material of the shielding pattern comprises indium tin oxide, and the insulating layer is an inorganic insulating layer.

5. The display panel according to claim 1, wherein the groove comprises one or more first groove walls, wherein the first groove wall and the substrate are perpendicular to each other, and the first trace pattern and the second trace pattern are patterns formed by fracture at the first groove wall.

6. The display panel according to claim 1, further comprising a bridging line, wherein the groove comprises one or more second groove walls, an obtuse included angle is formed between the second groove wall and a groove bottom, and the bridging line is bridged on the second groove wall with one end disposed on the insulating layer and the other end connected to the first trace pattern.

7. The display panel according to claim 6, wherein the bridging line and the first trace pattern are in a same layer.

8. The display panel according to claim 6, further comprising a first planarization layer, a third trace pattern, a second planarization layer, a source-drain trace pattern, a third planarization layer, and an anode pattern, which are sequentially stacked, along a direction away from the substrate, on the substrate having the second trace pattern.

9. The display panel according to claim 1, comprising a light-transmitting display region and a conventional display region at least partially surrounding the light-transmitting display region; wherein
the display panel further comprises a plurality of light-emitting devices and a plurality of pixel drive circuits disposed in the conventional display region, wherein the plurality of pixel drive circuits comprise a plurality of first pixel drive circuits and a plurality of second pixel drive circuits, and the plurality of first pixel drive circuits are electrically connected to the light-emitting devices disposed in the conventional display region; and
the display panel further comprises a light-emitting device disposed in the light-transmitting display region, wherein the plurality of second pixel drive circuits are electrically connected, through the first trace pattern and the second trace pattern, to the light-emitting device disposed in the light-transmitting display region.

10. The display panel according to claim 1, wherein materials of the first trace pattern and the second trace pattern comprise indium tin oxide.

11. The display panel according to claim 1, comprising a display region, wherein the first trace pattern and the second trace pattern are both disposed in the display region.

12. A method for manufacturing a display panel, comprising:
providing a substrate;
forming an insulating material layer on the substrate;
acquiring an insulating layer by forming a patterned groove on the insulating material layer; and
forming a first trace pattern and a second trace pattern on the insulating layer, wherein the first trace pattern is disposed in the groove, the second trace pattern is disposed on the insulating layer, and the first trace pattern and the second trace pattern are patterns formed by fracture at an edge of the groove.

13. The method according to claim 12, wherein acquiring the insulating layer by forming the patterned groove on the insulating material layer comprises:
forming a shielding pattern on the insulating material layer; and
acquiring the insulating layer with the patterned groove by processing the insulating material layer, wherein an edge of the shielding pattern protrudes out of an edge of an end, distal from the substrate, of a groove wall of the groove; and
forming the first trace pattern and the second trace pattern on the insulating layer comprises:
forming a conductive material layer on the substrate having the insulating layer formed thereon, the conductive material layer fracturing at the edge of the groove; and
acquiring the first trace pattern and the second trace pattern by processing the conductive material layer.

14. The method according to claim 13, wherein a material of the shielding pattern comprises indium tin oxide, and forming the shielding pattern on the insulating material layer comprises:
forming an indium tin oxide layer on the insulating material layer; and
acquiring the shielding pattern by wet-etching the indium tin oxide layer.

15. The method according to claim 13, wherein acquiring the insulating layer with the patterned groove by processing the insulating material layer comprises:
forming a photoresist pattern on the substrate having the shielding pattern formed thereon, wherein an orthographic projection of the shielding pattern on the substrate is within an orthographic projection of the photoresist pattern on the substrate; and
acquiring the insulating layer with the patterned groove by processing the insulating material layer by taking the photoresist pattern as a mask.

16. The method according to claim 1315, wherein the insulating layer is an inorganic insulating layer, and acquiring the insulating layer with the patterned groove by processing the insulating material layer by taking the photoresist pattern as the mask comprises:
acquiring the insulating layer with the patterned groove by performing dry-etching on the insulating material layer by taking the photoresist pattern as the mask.

17. The method according to claim 13, wherein acquiring the first trace pattern and the second trace pattern by processing the conductive material layer comprises:
coating the conductive material layer with a photoresist layer;
processing the photoresist layer into a photoresist pattern through an exposure process and a development process; and
acquiring the first trace pattern and the second trace pattern by processing the conductive material layer by taking the photoresist pattern as a mask.

18. A display device, comprising a sensor and a display panel, wherein the display panel comprises:
a substrate,
an insulating layer disposed on the substrate and provided with a patterned groove; and
a first trace pattern and a second trace pattern, wherein the first trace pattern is disposed in the groove, the second trace pattern is disposed on the insulating layer, and the first trace pattern and the second trace pattern are patterns formed by fracture at an edge of the groove.

19. The display device according to claim 18, wherein the sensor comprises at least one of a biological information sensor, an optical sensor, and a distance sensor.

20. The display device according to claim 19, wherein the display panel comprises a light-transmitting display region and a conventional display region at least partially surrounding the light-transmitting display region, the sensor is disposed on a back surface of the display panel, and an overlapping region is present between an orthographic projection of the sensor on the display panel and the light-transmitting display region.
